(19) United States
(12) Patent Application Publication
(10) Pub. No.: US 2009/0009197 A1
(43) Pub. Date: Jan. 8, 2009

(54) PROBE FOR ELECTRICAL TEST

(75) Inventors: Hideki HIRAKAWA, Aomori (JP); Akira SOUMA, Aomori (JP); Yoshikazu URUSHIYAMA, Aomori (JP)

Correspondence Address: INGRASSIA FISHER & LORENZ, P.C., 7010 E. COCHISE ROAD, SCOTTSDALE, AZ, 85253, US

(73) Assignee: KABUSHIKI KAISHA NIHON MICRONICS, Tokyo (JP)

(21) Appl. No.: 11/772,796

(22) Filed: Jul. 2, 2007

(51) Int. Cl. G01R 31/02

(52) U.S. Cl. 324/754

(57) ABSTRACT

A probe for electrical test comprises an arm region extending in a first direction, and a tip region leading to one side in a second direction intersecting the first direction of the arm region, and has a plate form making a direction interesting the first and second directions a thickness direction. The tip region includes a pedestal portion leading to the arm region and a contact portion leading to the pedestal portion, and the contact portion includes a base portion forming a part of the pedestal portion and a projecting portion leading to the base portion and projecting from the pedestal portion in the second direction. By this, damage to the contact portion is prevented.

### TECHNICAL FIELD

The present invention relates to a probe for use in an electrical test of a flat plate-like device under test such as a semiconductor integrated circuit.

### BACKGROUND

A flat plate-like device under test such as a semiconductor integrated circuit is subjected to an electrical test as to whether or not it is manufactured as per specification. Such an electrical test is conducted by using an electrical connecting apparatus such as a probe card, a probe block, a probe unit and the like which are provided with a plurality of contacts, i.e., probes to be pressed individually against electrodes of the device under test. This type of electrical connecting apparatus is used for electrically connecting electrodes of a device under test and a tester.

Probes for use in this type of electrical connecting apparatus include needle-type one made of a conductive metal fine wire, a blade-type one formed like a plate, a probe element-type one using a probe element in which projected electrodes are formed on wiring formed on one of the faces of an electrically insulating sheet (film), and so forth.

The blade-type probe include a single plate-type one made of a conductive metal plate, and a lamination-type one in which exposure of a photoresist and etching as well as plating to the etched portion are conducted once or more.

Probes of any types are supported like a cantilever on a support member such as a wiring board with their tips pressed against electrodes of a device under test. When the tips are pressed against the electrodes of the device under test, the probes are curved due to elastic deformation.

The blade-type probe includes: one comprising a first and a second arm portions extending in a first direction at an interval in a second direction; a first and a second connecting portions respectively connecting the first and second arm portions respectively at their front end portions and base end portions, a tip portion leading to one side in the second direction of the first connecting portion, and a mounting portion leading to the other side in the second direction of the second connecting portion (Patent Document 1).

Patent Document 1: WO 2004-102207 Official Gazette A1

In the conventional probe, the tip portion includes a pedestal portion leading to the first connecting portion, and a contact portion (tip) integrally leading to the pedestal portion.

Such a probe as mentioned above is attached at its mounting portion to a suitable support member and is supported on the support member like a cantilever, to be pressed at its tip against an electrode in that state. By this, an excessive overdrive acts on the probe, thereby curving the probe at its first and second arm portions due to elastic deformation.

In the conventional probe, however, when an overdrive acts, the contact portion is subjected to damage such as breakage. Particularly, in case of a microprobe for integrated circuit, a contact portion is very small and the mechanical strength of the contact portion is weak, so that the contact portion is prone to be broken at the joint portion with the pedestal portion by the overdrive, and it is difficult to increase the overdrive amount and greatly elastically deform the first and second arm portions.

Unless the overdrive amount cannot be increased such as above, the pressing force (needle pressure) of the tip to the electrode of the device under test cannot be increased, so that the electrodes of the device under test and the tips cannot be brought into a favorable state of electrical connection, and the positions of the tips in the second direction should be coincided highly accurately. As a result, an accurate test is not realized.

### BRIEF SUMMARY

### Problem to Be Solved

An object of the present invention is to prevent damage to a contact portion.

### Means to Solve Problem

The probe for electrical test according to the present invention comprises an arm region extending in one direction; and a tip region leading to one side in a second direction intersecting the first direction of the arm region and has a plate-like shape of which a direction intersecting the first and second directions is a thickness direction. The tip region includes a pedestal portion leading to the arm region, and a contact portion leading to the pedestal portion, wherein the contact portion includes a base portion forming a part of the pedestal portion, and a projecting portion leading to the base portion and projecting from the pedestal portion in the second direction.

### EFFECT OF THE INVENTION

In the probe of the present invention, the projecting portion is pressed against the electrode of the device under test. However, since the base portion of the contact portion forms a part of the pedestal portion, the contact area of the contact portion with the pedestal portion is greater than the conventional probe. Therefore, damage to the contact portion is prevented.

The arm region includes a first and a second arm portions extending in the first direction at an interval in the second direction, and a first and a second joint portions connecting the first and second arm portions respectively at their front end portions and base end portions, and the tip region may be formed to integrally lead to the first joint portion or the second arm portion.

The probe according to the present invention can further comprise an extension region leading to the other side in the second direction of the second joint portion, and a mounting region leading to the other side in the second direction of the extension region.

The base portion of the contact region may have a configuration such as L-letter shape, U-letter shape, T-letter shape or Y letter-shape.

The base portion of the contact region may form a part of the surface of the pedestal portion. In place thereof, the base portion of the contact region may be embedded in the pedestal portion.

The contact portion is made of a metal material of high hardness, and the arm region may be made of a metal material of high tenacity.

### BRIEF DESCRIPTION OF THE DRAWINGS

FIG. 1 is a front elevation showing a first embodiment of the probe of the present invention.

FIG. 2 is a right side view of the probe in FIG. 1.

FIG. 3 is a right side view showing a second embodiment of the present invention.

FIG. 4 is a right side view showing a third embodiment of the probe of the present invention.

FIG. 5 is a right side view showing a fourth embodiment of the probe of the present invention.

FIG. 6 is a right side view showing a fifth embodiment of the probe of the present invention.

FIG. 7 is a flow chart showing one embodiment of production method of the probe in FIG. 1.

FIG. 8 is a flow chart to explain a process following FIG. 7.

FIG. 9 is a flow chart to explain a process following FIG. 8.

FIG. 10 is a flow chart to explain a process following FIG. 9.

### DETAILED DESCRIPTION

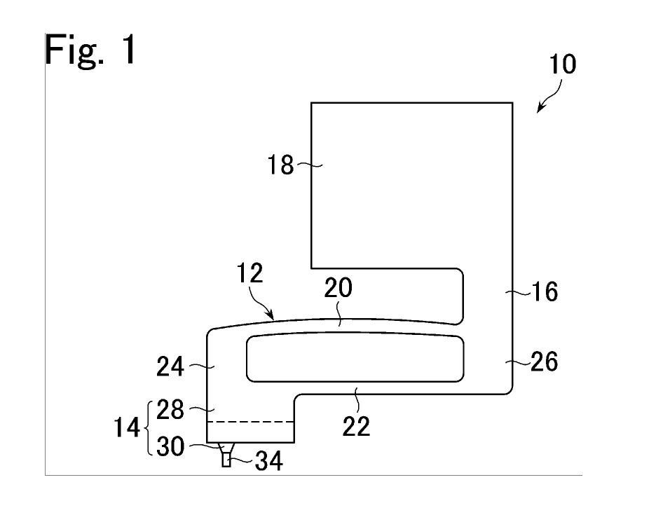

In FIG. 1, the rightward and leftward direction is called a first direction, the vertical direction is called a second direction, and the perpendicular direction to the sheet surface is called a third direction. Those directions are different depending on a chuck top of a prober to receive a device under test to be energized.

### Embodiment 1

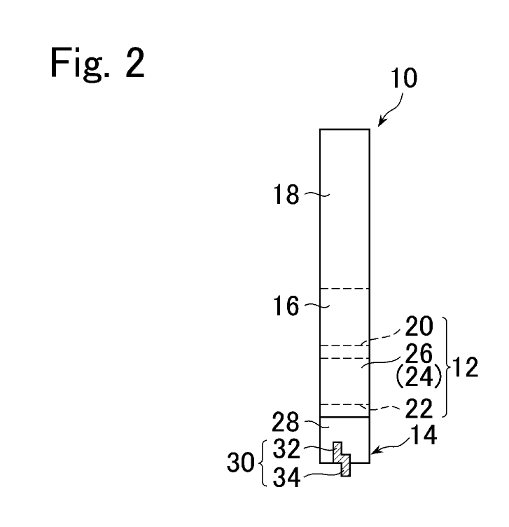

Referring to FIGS. 1 and 2, a probe 10 comprises an arm region 12 extending in the first direction (rightward and leftward direction), a tip region 14 integrally leading to the lower edge of the front end portion of the arm region 12, an extension region 16 integrally leading to the upper edge of the base end portion of the arm region 12, and a mounting region 18 integrally leading to the upper edge of the extension region 16.

The arm region 12 includes a first and a second arm portions 20, 22 extending in the first direction at an interval in the second direction (vertical direction), and a first and a second joint portions 24, 26 respectively connecting the first and second arm portions 20, 22 at their front end portions and base end portions.

The tip region 14 has a pedestal portion 28 integrally leading to the lower edge of the front end portion of the second arm portion 22 and to the lower edge of the first joint portion 24, and a contact portion 30 projecting from the lower edge of the pedestal portion 28, and is projected downward from the lower edge on the front end side of the first joint portion 24.

The arm region 12, extension region 16, mounting region 18 and pedestal portion 28 have an integral plate-like shape having substantially the same thickness, so that the probe 10 is formed to be a probe of a blade type which is generally flat.

On the other hand, a contact portion 30 includes, as shown in FIG. 2, a base portion 32 forming a part of the pedestal portion 28, a projecting portion 34 leading to the base portion 32 and projecting downward from the pedestal portion 28, and has a generally crank-like sectional shape. The base portion 32 has an L-like sectional configuration and is embedded in the pedestal portion 28.

The contact portion 30 has a downward front end face at the lower end. In the illustration, the front end face acts as a tip to be pressed against an electrode of a device under test. However, the tip may be an acute needle point instead of a face.

When seen in FIG. 1, the width dimension of the pedestal portion 28 in the rightward and leftward direction is longer than the width dimension of the first joint portion 24 in the rightward and leftward direction. For this reason, the pedestal portion 28 has a width dimension extending from the lower edge of the first joint portion 24 to the lower edge on the front end side of the second arm portion 22. The width dimension of the pedestal portion 28 in the rightward and leftward direction, however, may have the same value as that of the first joint portion 24 in the same direction.

The width dimension of the extension region 16 in the rightward and leftward direction is the same as that of the second joint portion 26 in the same direction. The width dimension of the extension region 16 in the rightward and leftward direction may have a different value from that of the second joint portion 26 in the rightward and leftward direction.

As a material of the probe 10, conductive metal materials such as nickel-phosphor alloy (Ni—P), nickel-tungsten alloy (Ni—W), rhodium (Rh), phosphor bronze (P—Sn—Cu), nickel (Ni), palladium-cobalt alloy (Pd—Co), palladium-nickel-cobalt alloy (Pd—Ni—Co) and the like can be enumerated.

The entire probe 10 can be made of any of the above-mentioned materials. It is possible, however, to make the contact portion 30 of another material different from other parts 12, 14, 16, 28, etc.

In the latter case, it is possible to make the contact portion 30 of a metal material of high hardness such as rhodium, and other parts 12, 14, 16 and 28 may be made of a metal material of high tenacity such as nickel. By this, even by making a great overdrive act on the probe 10, the arm region 12 largely deflects, thereby preventing the probe 10 from breaking.

Also, making the entire probe 10 of the same material, or making other parts excluding the contact portion 30 of the same material facilitates production of the probe 10.

The probe 10 is assembled into an electrical connecting apparatus such as a probe card. As such an electrical connecting apparatus is described in Patent Document 1, a detailed explanation thereof is omitted. Such an electrical connecting apparatus supports a plurality of probes 10 at the mounting portions 18 on the mounting plate like a cantilever.

In the probe 10, the tip of the contact portion is pressed against an electrode of a device under test in a state of being supported on the mounting plate of the electrical connecting apparatus like a cantilever.

When the tip is pressed against the electrode of the device under test, an overdrive OD acts on the probe 10, to elastically deform and curve both arm portions 20, 22.

However, since the base portion 32 of the contact portion 30 forms a part of the pedestal portion 28, a contact area of the contact portion 30 with the pedestal portion 28 is greater than that of the conventional probe, thereby preventing breakage of the contact portion 30 such as falling off from the pedestal portion 28.

### Embodiment 2

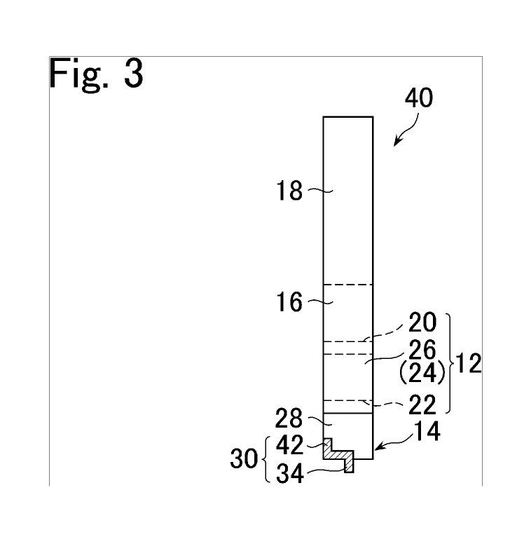

In place of embedding the base portion 32 in the pedestal portion 28, like a probe 40 as shown in FIG. 3, the base portion 42 of the contact portion 30 may be enlarged to have the base portion 42 form a part of the side face and underside of the pedestal portion.

### Embodiment 3

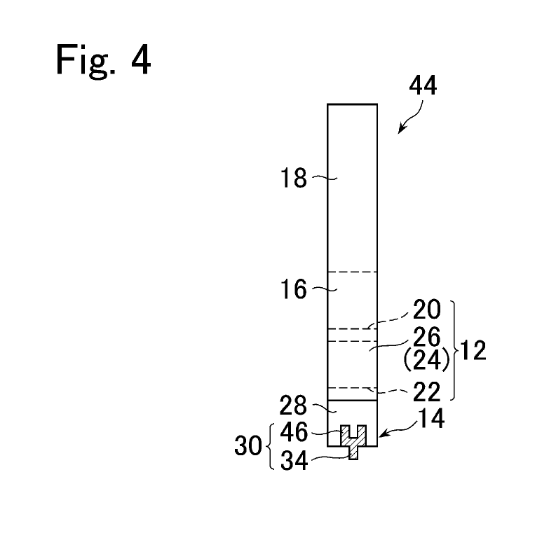

In the probe 44 shown in FIG. 4, the sectional shape of the base portion 46 of the contact portion 30 is U-shaped, and the sectional shape of the contact portion 30 is Y-shaped. The base portion 46 is embedded in the pedestal portion 28. This probe 44 also displays the same action and effect as the probe 10 does.

### Embodiment 4

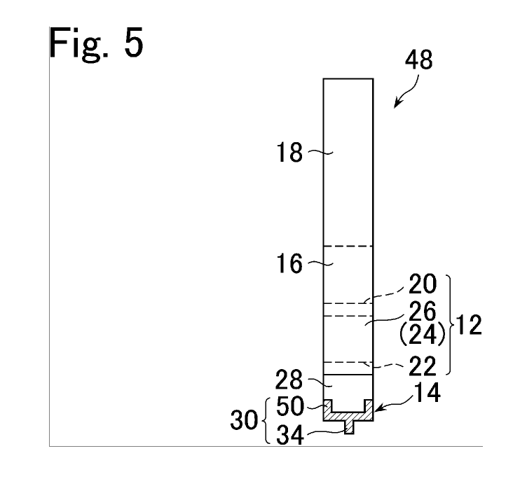

In place of embedding the base portion 46 in the pedestal portion 28, like a probe 48 shown in FIG. 5, the base portion 50 of the contact portion 30 may be enlarged, and the base portion 50 may form a part of the side faces and underside of the pedestal portion 28.

### Embodiment 5

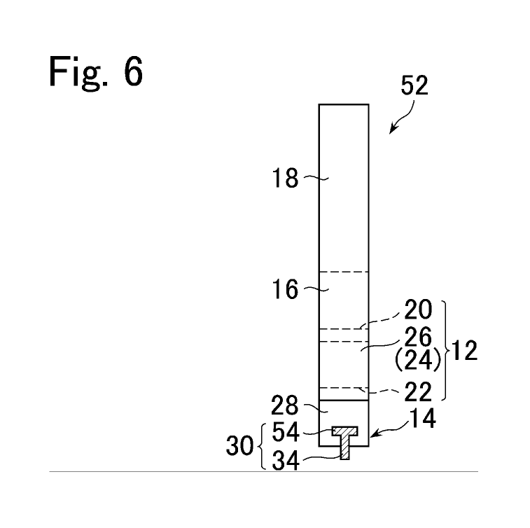

In a probe 52 shown in FIG. 6, the sectional configuration of the base portion 54 of the contact portion 30 is T-shaped, and the sectional configuration of the contact portion 30 is T-shaped. The base portion 54 is embedded in the pedestal portion 28. This probe 52 also displays the same action and effect as the probe 10.

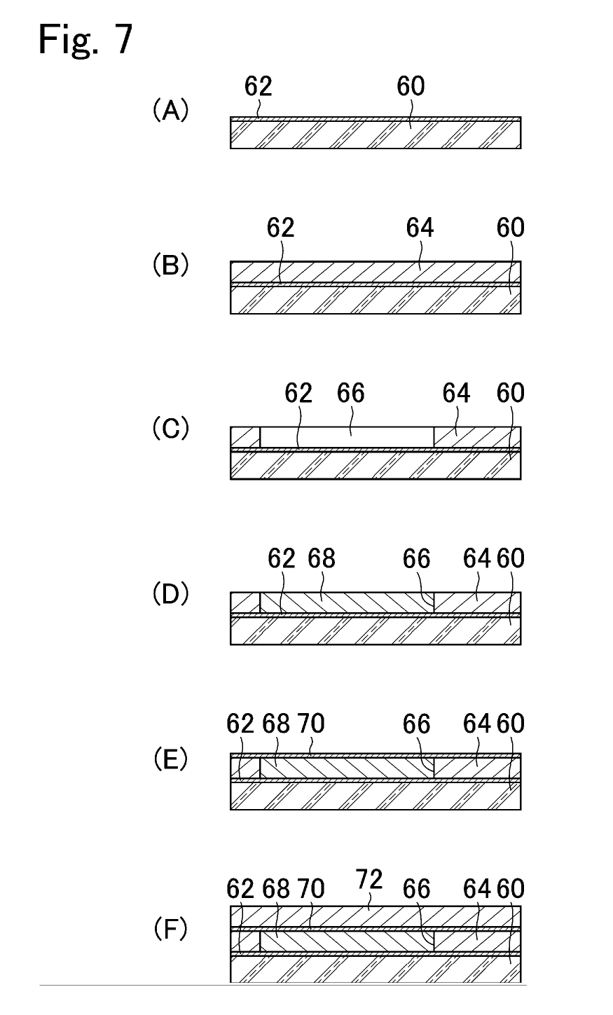

Referring to FIGS. 7 through 10, an example of production method of the probe 10 which has a structure as shown in FIGS. 1 and 2.

First, as shown in FIG. 7(A), a metal layer 62 such as a nickel layer is formed on one face of a stainless steel plate-like base material 60 by sputtering.

Next, as shown in FIG. 7(B), a photoresist 64 is applied to the metal layer 62.

Then, as shown in FIG. 7(C), the photoresist 64 is exposed and developed so as to form a recess 66 corresponding to the arm region 12, extension region 16, mounting region 18 and a part of the pedestal portion 28.

Then, as shown in FIG. 7(D), a metal layer 68 serving as the arm region 12, extension region 16, mounting region 18 and a part of the pedestal portion 28 is formed on the recess 66 by electroplating using a metal material of high tenacity such as nickel-chromium alloy.

Then, as shown in FIG. 7(E), a metal layer 70 such as a nickel layer is formed on the photoresist 64 and metal layer 68 by sputtering.

Then, as shown in FIG. 7(F), a photoresist 72 is applied to the metal layer 70.

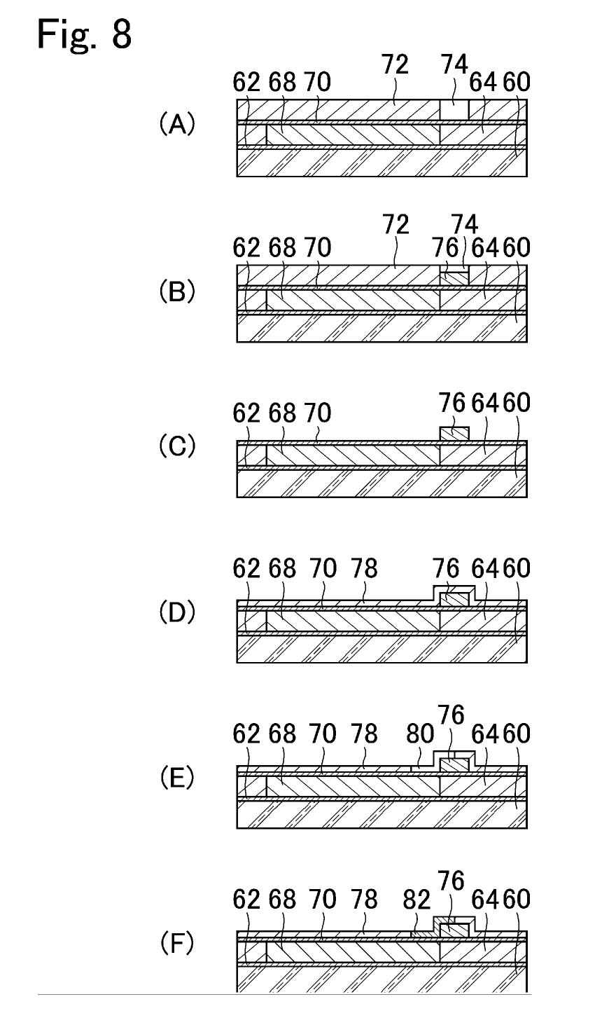

Then, as shown in FIG. 8(A), the photoresist 72 is exposed and developed so as to form a recess 74 on the photoresist 72.

Then, as shown in FIG. 8(B), a sacrifice layer 76 to be removed later is formed on the recess 74 by electroplating.

Then, as shown in FIG. 8(C), the photoresist 72 is removed to expose the metal layer 70 and sacrifice layer 76.

Then, as shown in FIG. 8(D), a photoresist 78 is applied to the metal layer 70 and sacrifice layer 76.

Then, as shown in FIG. 8(E), the photoresist 72 is exposed and developed so as to form a recess 80 corresponding to the contact portion 30 on the photoresist 78.

Then, as shown in FIG. 8(F), a metal layer 82 serving as the contact portion 30 is formed in the recess 80 by electroplating by a metal material of high tenacity such as rhodium.

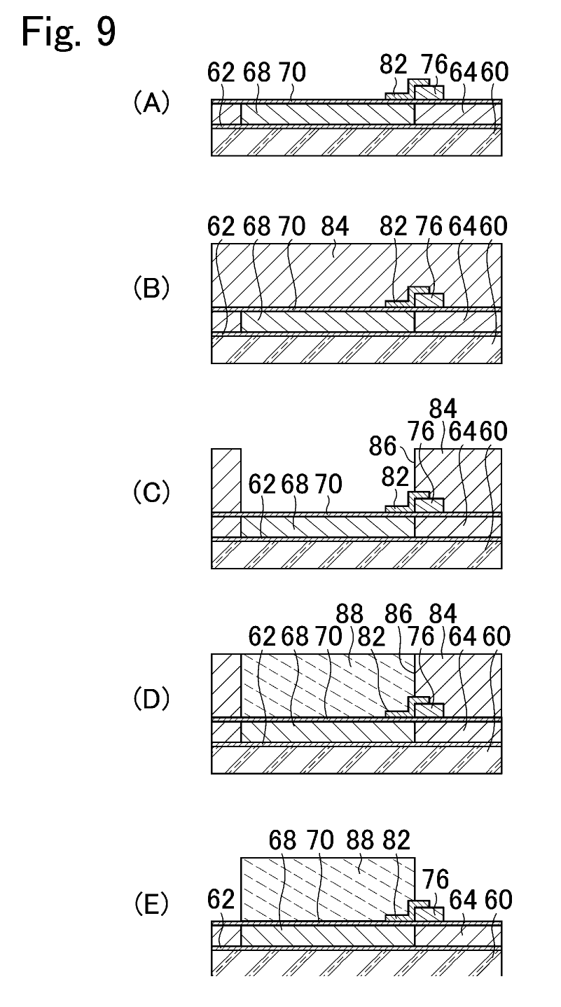

Then, as shown in FIG. 9(A), the photoresist 78 is removed to expose the metal layers 70, 82 and sacrifice layer 76.

Then, as shown in FIG. 9(B), the photoresist 84 is applied to the metal layers 70, 82 and sacrifice layer 76.

Then, as shown in FIG. 9(C), the photoresist 84 is exposed and developed so as to form a recess 86 corresponding to the arm region 12, extension region 16, mounting region 18 and the remaining part of the pedestal portion 28 on the photoresist 84.

Then, as shown in FIG. 9(D), a metal layer 88 serving as the arm region 12, extension region 16, mounting region 18 and the remaining part of the pedestal portion 28 is formed in the recess 86 by electroplating using a metal material of high tenacity such as nickel-chromium alloy.

Then, as shown in FIG. 9(E), the remaining part of the photoresist 84 is removed to expose the metal layers 70, 82 and sacrifice layer 76.

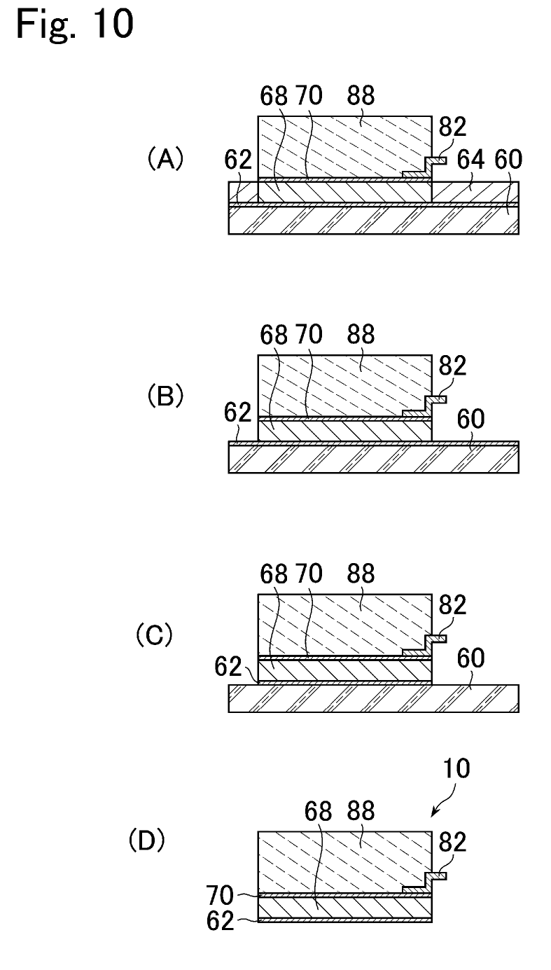

Then, as shown in FIG. 10(A), a part of the metal layer 70 and the sacrifice layer 76 are removed by etching.

Then, as shown in FIG. 10(B), the remaining part of the photoresist 64 is removed to expose the metal layer 62.

Then, as shown in FIG. 10(C), a part of the metal layer 62 is removed by etching to expose the base material 60.

Then, as shown in FIG. 10(D), the metal layers 62, 68, 70, 82 and 88 are separated from the base material 60. Thereby, the probe 10 is produced.

In the foregoing production method, the metal layers 62 and 70 are to enhance adhesive property of the metal layers 68, 82 and 88; therefore, they may be omitted depending on the metal materials used for the metal layers 68, 82 and 88.

The other probes 40, 44, 48 and 52 can also be produced as mentioned above by using electroplating, sputtering, photolithography, etching and the like.

### INDUSTRIAL APPLICABILITY

The present invention is not limited to the above embodiments but can be variously modified without departing from its purport.

1. A probe for electrical test comprising an arm region extending in a first direction and a tip region leading to one side in a second direction intersecting the first direction of said arm region, and having a plate form, making a third direction intersecting the first and second directions a thickness direction,
wherein said tip region includes a pedestal portion leading to said arm region and a contact portion leading to said pedestal portion, said contact portion including a base portion forming a part of said pedestal portion, and a projecting portion leading to said base portion and projecting from said pedestal portion in the second direction, and
wherein said base portion of said contact portion has such a configuration as L-letter shape, U-letter shape, T-letter shape or Y-letter shape, and continues integrally to the pedestal portion.

2. The probe for electrical test claimed in claim 1,
wherein said arm region includes a first and a second arm portions extending in the first direction at an interval in the second direction, and a first and a second joint portions respectively connecting said first and second arm portions at front end portions and base end portions, and
wherein said tip region integrally leads to said first joint portion or said second arm portion.

3. The probe for electrical test claimed in claim 2, further comprising:
an extension region leading to the opposite side to the side of said contact portion in the second direction of said second joint portion; and
a mounting region leading to the opposite side to the side of said contact portion in the second direction of said extension region.

4. (canceled)

5. The probe claimed in claim 1, wherein said base portion of said contact portion forms a part of the surface of said pedestal portion.

6. The probe claimed in claim 1, wherein said base portion of said contact region is embedded in said pedestal portion.

7. The probe claimed in claim 1, wherein said contact portion is made of a metal material of high hardness, and said arm region is made of a metal material of high tenacity.

8. The probe for electrical test claimed in claim 1, wherein said base portion and said projecting portion are made of a metal material having a higher hardness than that portion of said pedestal portion other than the base portion.
